(19) United States
(12) Patent Application Publication
(10) Pub. No.: US 2025/0280636 A1
(43) Pub. Date: Sep. 4, 2025

(54) MICRO LIGHT-EMITTING DIODE DISPLAY DEVICE

(71) Applicant: PlayNitride Display Co., Ltd., MiaoLi County (TW)

(72) Inventors: Sheng-Yuan Sun, MiaoLi County (TW); LOGANATHAN MURUGAN, MiaoLi County (TW); Po-Wei Chiu, MiaoLi County (TW)

(73) Assignee: PlayNitride Display Co., Ltd., MiaoLi County (TW)

(21) Appl. No.: 19/209,824

(22) Filed: May 16, 2025

Related U.S. Application Data
(62) Division of application No. 17/695,848, filed on Mar. 16, 2022.

(30) Foreign Application Priority Data
Jan. 19, 2022 (TW) 111102179

(51) Int. Cl. H10H 29/14; H10H 20/851; H10H 20/855

(52) U.S. Cl. CPC H10H 29/142; H10H 20/851; H10H 20/855

(57) ABSTRACT

A micro light-emitting diode display device includes a display substrate, multiple pixels, and at least one color conversion layer. The pixels are disposed on the display substrate. Each of the pixels includes multiple sub-pixels. Each of the sub-pixels includes at least one micro light-emitting diode. The at least one color conversion layer is disposed on the pixels. The at least one color conversion layer is continuously disposed on at least a part of sub-pixels of different pixels along a same direction.

### CROSS-REFERENCE TO RELATED APPLICATION

This application is a divisional application of and claims the priority benefit of U.S. application Ser. No. 17/695,848, filed on Mar. 16, 2022, which claims the priority benefit of Taiwan application serial no. 111102179, filed on Jan. 19, 2022. The entirety of each of the above-mentioned patent applications is hereby incorporated by reference herein and made a part of this specification.

### BACKGROUND

### Technical Field

The disclosure relates to a display device, and more particularly, relates to a micro light-emitting diode display device.

### Description of Related Art

One of the main applications in the micro light-emitting diode display industry today is to deploy quantum dots on the micro light-emitting diode display device, thereby increasing the color gamut of the display. Lithography and inkjet printing (IJP) are processes that are compatible with quantum dot materials, wherein the cost of inkjet printing is lower than that of lithography. At present, inkjet printing is typically adopted to produce quantum dot display devices.

When the resolution of the display device is higher, the pixel density is higher, and when the size of the light-emitting chip is smaller, the process accuracy of inkjet printing has its limit, resulting in poor yield. In addition, there is room for improvement in the light conversion rate of quantum dot display devices.

### SUMMARY

The disclosure provides a micro light-emitting diode display device, which can improve the yield.

In an embodiment of the disclosure, a micro light-emitting diode display device includes a display substrate, a plurality of pixels, at least one color conversion layer, a plurality of first blocking layers and a plurality of second blocking layers. The plurality of pixels are disposed on the display substrate, each of the pixels includes a plurality of sub-pixels, and each of the sub-pixels includes at least one micro light-emitting diode. The at least one color conversion layer is disposed on the pixels. The at least one color conversion layer is continuously disposed on at least a part of sub-pixels of different pixels along a same direction. Each of the first blocking layers is respectively disposed between two adjacent pixels with a same color conversion layer. Each of the second blocking layers is respectively disposed between two sub-pixels covered by the color conversion layer of each of the pixels.

Based on the above, in the micro light-emitting diode display device of the embodiment of the disclosure, since the color conversion layer is continuously disposed on the sub-pixels of the pixel along the same direction, the position tolerance of the color conversion layer during manufacture can be increased, improving the yield. Since the color conversion layer has a larger area, the light conversion rate of the micro light-emitting diode display device can be improved to achieve better display quality.

### BRIEF DESCRIPTION OF THE DRAWING

FIG. 1 is a top schematic view of a micro light-emitting diode display device according to an embodiment of the disclosure.

FIG. 2A is a cross-sectional schematic view of the micro light-emitting diode display device of FIG. 1 along a line A-A′.

FIG. 2B is a cross-sectional schematic view of the micro light-emitting diode display device of FIG. 1 along a line B-B′.

FIG. 2C is a cross-sectional schematic view of the micro light-emitting diode display device of FIG. 1 along a line C-C′.

FIG. 3 is a schematic view of sub-pixels of a micro light-emitting diode display device according to an embodiment of the disclosure.

FIG. 4 is a cross-sectional schematic view of a micro light-emitting diode display device according to an embodiment of the disclosure.

FIG. 5 is a cross-sectional schematic view of a micro light-emitting diode display device according to an embodiment of the disclosure.

FIG. 6 is a top schematic view of a micro light-emitting diode display device according to an embodiment of the disclosure.

FIG. 7 is a cross-sectional schematic view of the micro light-emitting diode display device of FIG. 6 along a line B-B′.

FIG. 8 is a cross-sectional schematic view of a micro light-emitting diode display device according to an embodiment of the disclosure.

FIG. 9 is a top schematic view of a micro light-emitting diode display device according to an embodiment of the disclosure.

FIG. 10A is a top schematic view of a micro light-emitting diode display device according to an embodiment of the disclosure.

FIG. 10B is a top schematic view of a micro light-emitting diode display device according to an embodiment of the disclosure.

### DETAILED DESCRIPTION OF DISCLOSED EMBODIMENTS

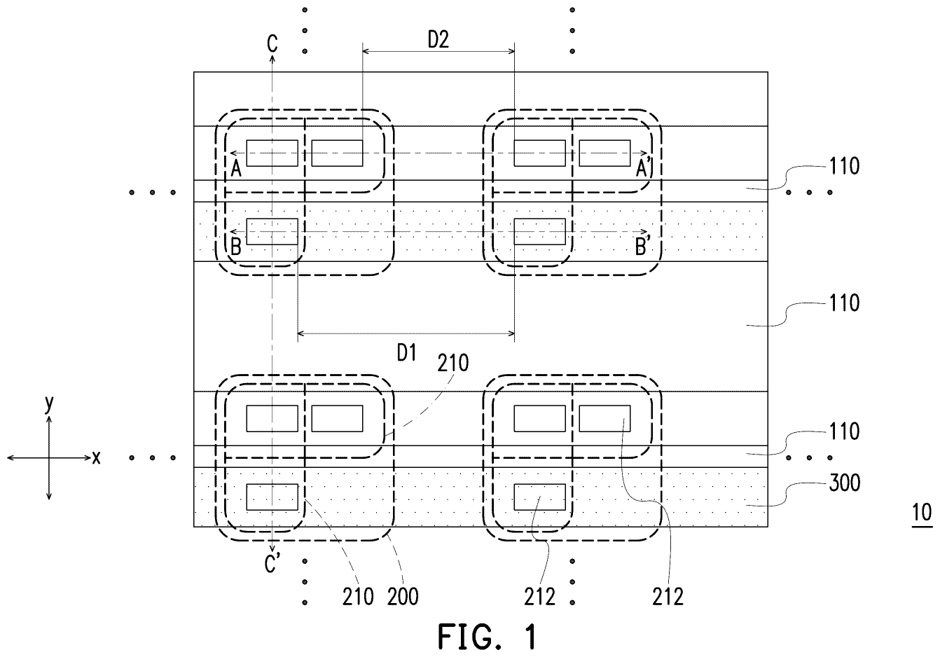

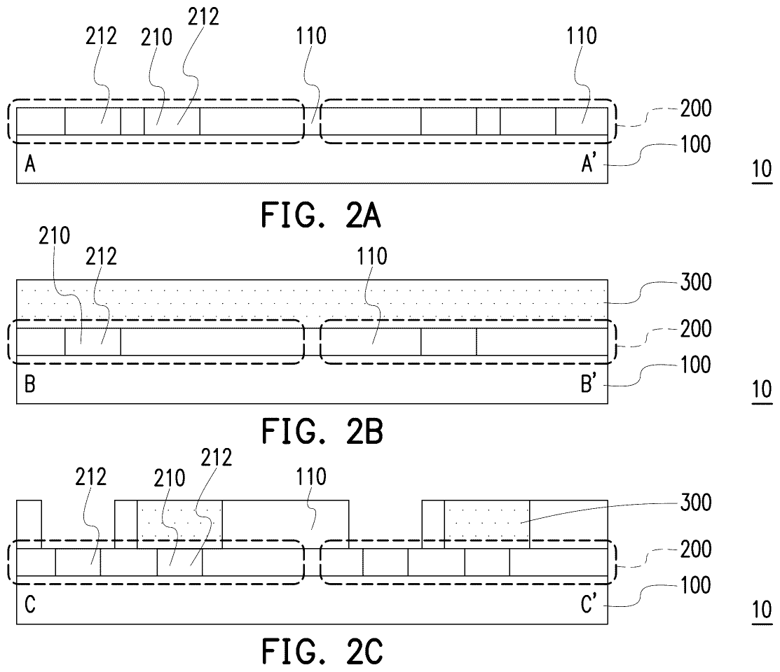

FIG. 1 is a top schematic view of a micro light-emitting diode display device according to an embodiment of the disclosure, FIG. 2A is a cross-sectional schematic view of the micro light-emitting diode display device of FIG. 1 along a line A-A′, FIG. 2B is a cross-sectional schematic view of the micro light-emitting diode display device of FIG. 1 along a line B-B′, and FIG. 2C is a cross-sectional schematic view of the micro light-emitting diode display device of FIG. 1 along a line C-C′. Referring to FIG. 1 to FIG. 2C, a micro light-emitting diode display device 10 includes a display substrate 100, multiple pixels 200 and at least one color conversion layer 300. In this embodiment, the display substrate 100 is, for example, a complementary metal oxide semiconductor substrate, a liquid-crystal-on-silicon substrate, a thin film transistor substrate, a printed circuit board, or other display substrates with operating circuits. Multiple pixels 200 are disposed on the display substrate 100, and each of the pixels 200 includes multiple sub-pixels 210, each of the sub-pixels 210 include at least one micro light-emitting diode (micro LED) 212, (a micro light-emitting diode is illustrated herein as an example). The micro light-emitting diode 212, for example, emits blue light or ultraviolet light. At least one color conversion layer 300 is disposed on the pixel 200. At least one color conversion layer 300 is continuously disposed in at least a part of the multiple sub-pixels 210 of different pixels 200 along the same direction (in FIG. 1, one color conversion layer 300 is continuously disposed in a part of multiple sub-pixels 210 of different pixels 200 along the same direction (that is, each of the sub-pixels 210 of the pixel 200 at the bottom of FIG. 1 in FIG. 1) as an example). However, in other embodiments, the color conversion layers 300 of multiple different colors may be successively disposed in the sub-pixels 210 of the different pixels 200 along the same direction. In this embodiment, the color conversion layer 300 is a band-shaped quantum dot color conversion layer.

In detail, in the embodiments of FIG. 1 to FIG. 2C, the pixels 200 are arranged in an x direction and a y direction perpendicular to the x direction, but not limited thereto. In this embodiment, the color conversion layer 300 spans at least a part of the multiple sub-pixels 210 of different pixels 200 in the x-direction. Therefore, during the manufacturing process, due to the relationship of the arrangement of the nozzles of an inkjet printer (not shown) (in the embodiment that is not shown, the nozzles of the inkjet printer are arranged along the x-direction, for example), the requirements for the positional accuracy of the color conversion layer 300 on the x-direction are relatively loose. The larger tolerance of the color conversion layer 300 on the x-direction can reduce the possibility of defects in the inkjet printing process and improve the yield. In addition, since the color conversion layer 300 spans different pixels 200 in the x direction, the color conversion layer 300 has a larger area, which can improve the light conversion rate.

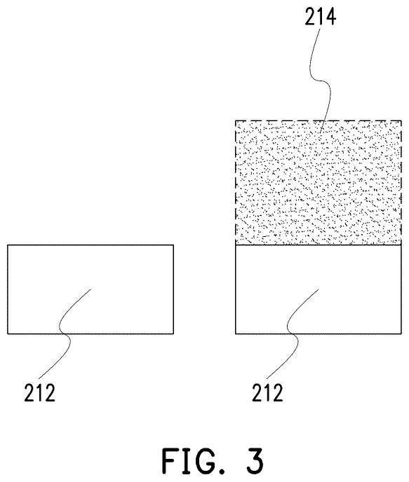

In particular, the sub-pixel that is not disposed with the color conversion layer may also include a color conversion structure on top, for example, FIG. 3 is a schematic view of sub-pixels of a micro light-emitting diode display device according to an embodiment of the disclosure. Referring to FIG. 1 to FIG. 3, for example, the micro light-emitting diode 212 of each of the sub-pixels 210 of each of the pixels in FIG. 1 is a blue micro light-emitting diode. The sub-pixel 210 on the right side in FIG. 3 is the blue light-emitting diode 212 in the pixel 200 located in the upper right corner of FIG. 1, on which a color conversion structure 214 that can be excited to emit green light may be disposed. The sub-pixel 210 on the left side in FIG. 3 is the blue light-emitting diode 212 in the pixel 200 located in the upper left corner of FIG. 1, which is not disposed with the color conversion structure 214 thereon. In the embodiment that is not shown, the sub-pixels of each of the pixels in FIG. 1, such as ultraviolet light-emitting diodes, may have more than one sub-pixel including a color conversion structure, so that the color rendering of each of the pixels 200 can be better. In this embodiment, the wavelength of the light of each of the sub-pixels 210 converted by the color conversion layer 300 is greater than the emission light wavelength of each of the sub-pixels 210 without the color conversion layer 300. The color conversion layer 300, for example, can be a quantum dot (QD) material that is excited to emit a red light, to increase the conversion efficiency of red light.

Continue referring to FIG. 1, in this embodiment, a first distance D1 is between two micro light-emitting diodes 212 of the sub-pixels 210 of two adjacent pixels 200 covered by the same color conversion layer 300, and a second distance D2 is between two micro light-emitting diodes 212 of the sub-pixels 210 of two adjacent pixels 200 not covered by a color conversion layer 300, the first distance D1 is greater than the second distance D2. In other words, the sub-pixels 210 in the pixel 200 are arranged, for example, in a triangle. Since the distance between two micro light-emitting diodes 212 of the sub-pixels 210 of the adjacent two pixels 200 covered by the same color conversion layer 300 is relatively large, a crosstalk between the adjacent pixels 200 whose emitted light angles become larger after a color conversion can be avoided, which improves the display quality. A reflective structure 110 may be disposed between the side surfaces of the micro light-emitting diodes 212 or between the sub-pixels 210 not covered by the same color conversion layer 300 to avoid crosstalk and increase a forward emitted light.

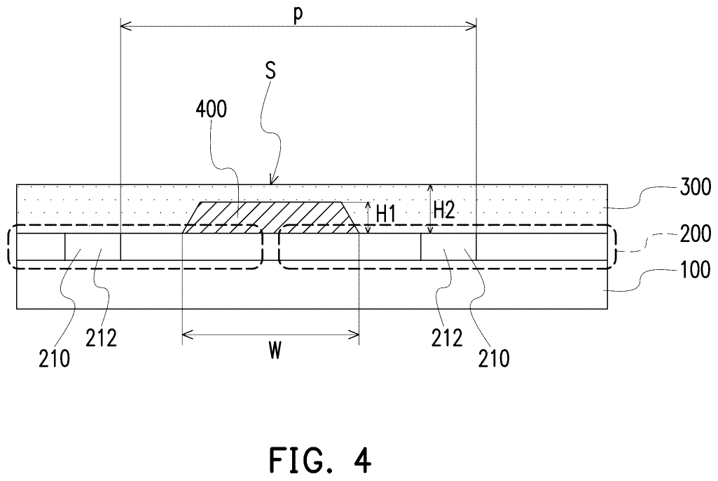

FIG. 4 is a cross-sectional schematic view of a micro light-emitting diode display device according to an embodiment of the disclosure. Referring to FIG. 4, a position of the cross-section on the micro light-emitting diode display device shown in FIG. 4 corresponds to a position of the cross-section on the micro light-emitting diode display device 10 shown in FIG. 2B. In this embodiment, the micro light-emitting diode display device 10 further includes multiple blocking layers 400, each of which is respectively disposed between two adjacent pixels 200 with the same color conversion layer 300. In this embodiment, the vertical cross-section of the blocking layer 400 perpendicular to a surface S of the micro light-emitting diode display device 10 is a trapezoid, which can concentrate the forward emitted light, and achieve a good anti-crosstalk effect between two adjacent pixels 200, but the disclosure is not limited thereto. In this embodiment, the blocking layer 400 is disposed between the color conversion layer 300 and the display substrate 100. In this embodiment, the blocking layer 400 is made of a material that can absorb light (e.g., black resin) or reflect light (white wall glue), so as to avoid crosstalk between two adjacent pixels 200. In addition, in this embodiment, the ratio of a first vertical height H1 of the blocking layer 400 to a second vertical height H2 of the color conversion layer 300 is greater than or equal to 0.5, and a pitch p is between two micro light-emitting diodes 212 of two adjacent sub-pixels 210 of two adjacent pixels 200. The ratio of a width W of each of the blocking layers 400 to the pitch p is greater than or equal to 0.5 to avoid crosstalk between two adjacent pixels 200.

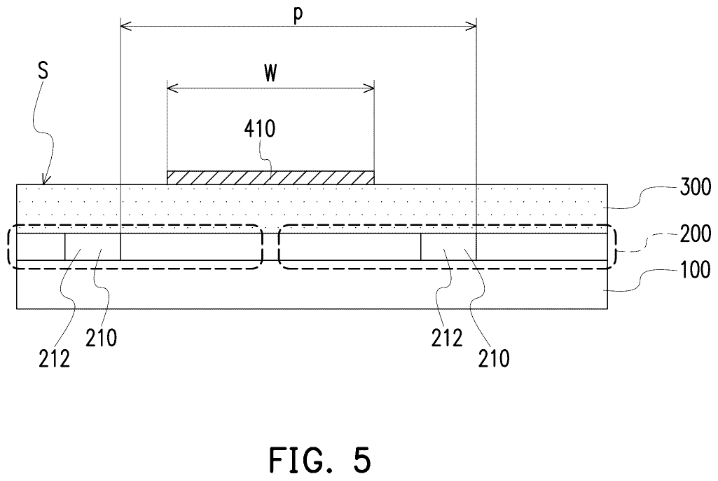

FIG. 5 is a cross-sectional schematic view of a micro light-emitting diode display device according to an embodiment of the disclosure. The position of the cross-section on the micro light-emitting diode display device shown in FIG. 5 corresponds to the position of the cross-section on the micro light-emitting diode display device shown in FIG. 2B. Referring to FIG. 5, in this embodiment, the micro light-emitting diode display device 10 further includes multiple light absorbing layers 410, each of the light absorbing layers 410 is respectively disposed between two adjacent pixels 200. In this embodiment, the light absorption layer 410 is disposed on the color conversion layer 300. In this embodiment, the light absorbing layer 410 is formed of a material that can absorb light, such as black resin, to avoid crosstalk between two adjacent pixels 200. In addition, in this embodiment, a pitch p is between two micro light-emitting diodes 212 of two adjacent sub-pixels 210 of two adjacent pixels 200, and the ratio of the width W of each of the light absorbing layers 410 to the pitch p is greater than or equal to 0.5, to avoid crosstalk between two adjacent pixels 200.

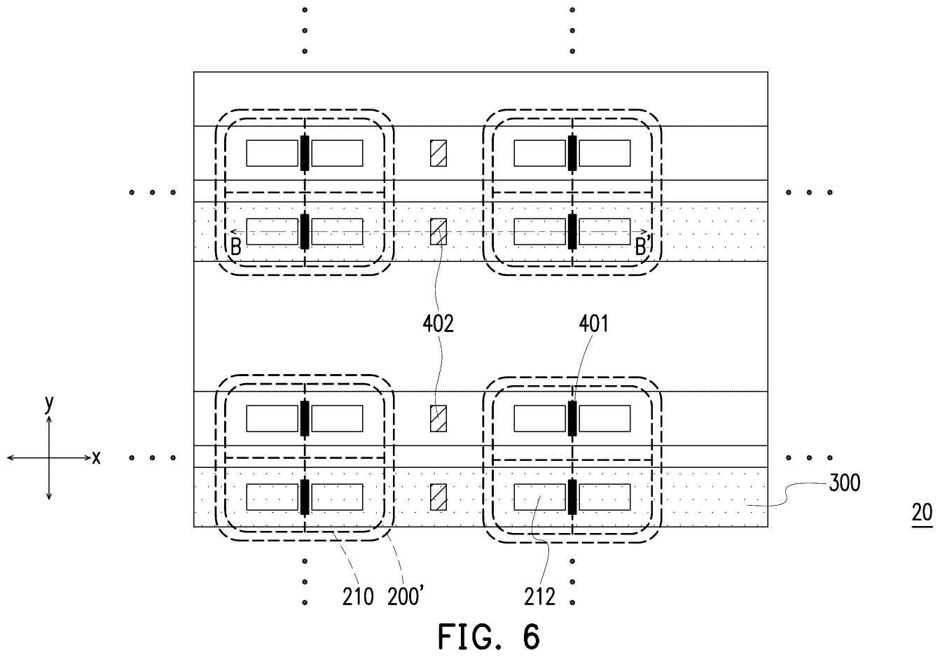

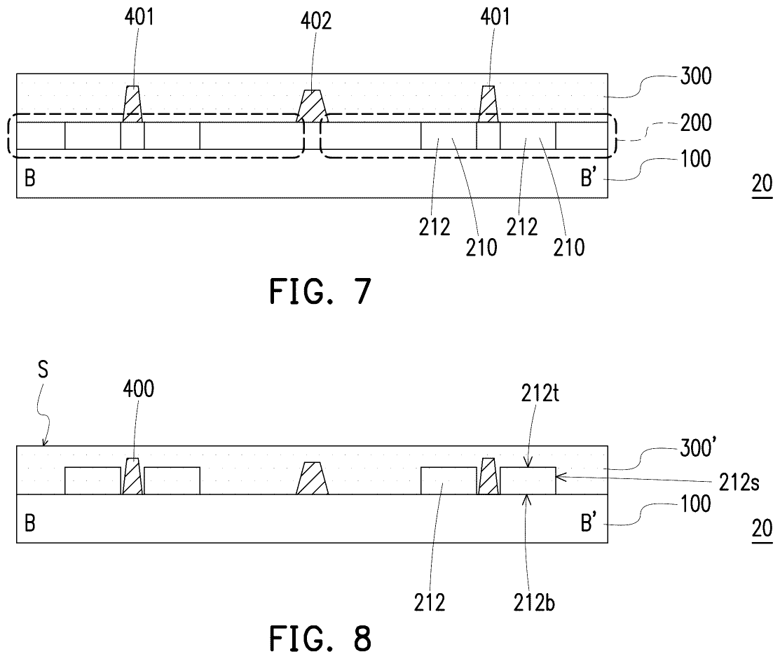

FIG. 6 is a top schematic view of a micro light-emitting diode display device according to an embodiment of the disclosure, and FIG. 7 is a cross-sectional schematic view of the micro light-emitting diode display device of FIG. 6 along a line B-B′. Referring to FIG. 6 and FIG. 7, in this embodiment, each of the pixels have at least four sub-pixels, and a color conversion layer 300 covers at least two of the sub-pixels 210 of each of the pixels 200′. Since the red light color conversion efficiency is poor, if the red color conversion layer covers two micro light-emitting diodes, the display efficiency can be increased. In this embodiment, a micro light-emitting diode display device 20 further includes multiple first blocking layers 401, and each of the first blocking layers 401 is respectively disposed between two micro light-emitting diodes 212 of two sub-pixels 210 covered by the color conversion layer 300 of each of the pixels 200′. In addition, in this embodiment, the micro light-emitting diode display device 20 further includes multiple second blocking layers 402, and each of the second blocking layers 402 is respectively disposed between two adjacent pixels 200. In the embodiment that is not shown, as long as the sub-pixels are sufficiently spaced apart, the blocking layers may not be provided.

FIG. 8 is a cross-sectional schematic view of a micro light-emitting diode display device according to an embodiment of the disclosure. Referring to FIG. 8, the position of the cross-section on the micro light-emitting diode display device shown in FIG. 8 corresponds to the position of the cross-section on the micro light-emitting diode display device 10 shown in FIG. 7, that is, the position of the cross-section along a line B-B′ of FIG. 6. The difference between FIG. 8 and FIG. 7 is that, in the embodiment of FIG. 8, the micro light-emitting diode 212 of the sub-pixel 210 has a top surface 212t and a bottom surface 212b parallel to the surface S of the micro light-emitting diode display device 20, and a side surface 212s connecting the top surface 212t and the bottom surface 212b, and a color conversion layer 300′ covers the top surface 212t and the side surface 212s of the corresponding micro light-emitting diode 212. The conversion efficiency can be increased by completely coating the top and side surfaces of the micro light-emitting diodes.

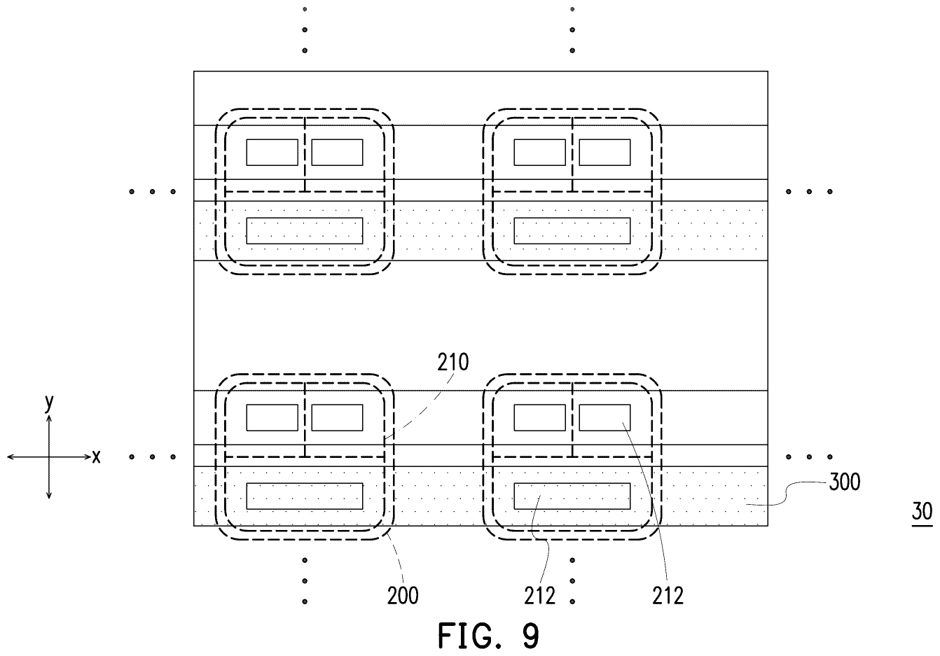

FIG. 9 is a top schematic view of a micro light-emitting diode display device according to an embodiment of the disclosure. A micro light-emitting diode display device 30 of the embodiment is similar to the micro light-emitting diode display device 10 of FIG. 1, and the difference between the two is that the area of the micro light-emitting diodes 212 covered by the color conversion layer 300 is larger than the area of the rest of the micro light-emitting diodes 212 not covered by the color conversion layer 300. When red light can be converted by the color conversion layer 300, since the color conversion efficiency of red light is poor, the color conversion efficiency can be increased by the larger area of the micro light-emitting diodes 212, thereby obtaining a better display effect.

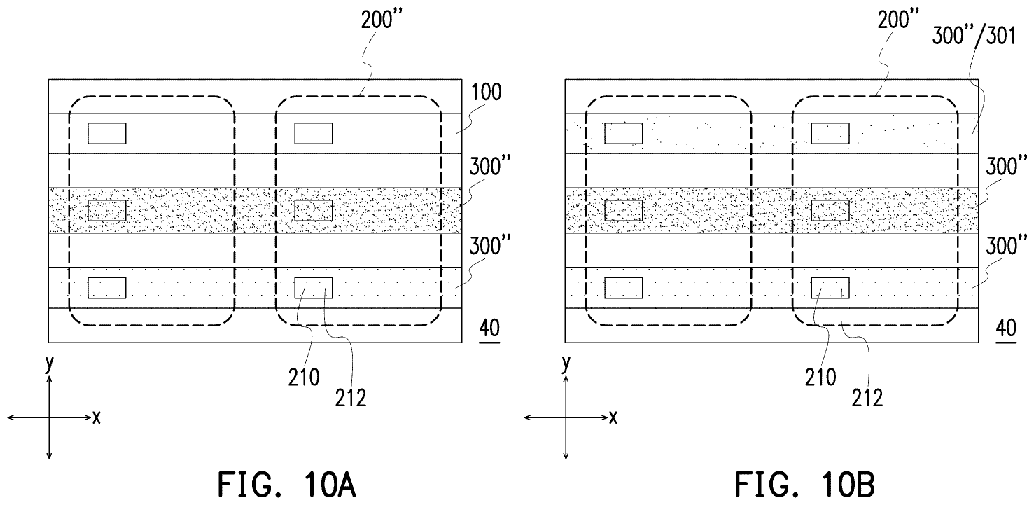

FIG. 10A is a top schematic view of a micro light-emitting diode display device according to an embodiment of the disclosure, and FIG. 10B is a top schematic view of a micro light-emitting diode display device according to an embodiment of the disclosure. In the embodiment of FIG. 10A, the number of at least one color conversion layer 300″ disposed on each of the pixels 200″ is two; in the embodiment of FIG. 10B, the number of at least one color conversion layer 300″ disposed on each of the pixels 200″ is two or three. The color conversion layers 300″ are respectively disposed on the sub-pixels 210 at different positions of the pixels 200″, and the color of light converted by the different color conversion layers 300″ are different from one another.

Specifically, in the embodiment of FIG. 10A, two color conversion layers 300″ are disposed on each of the pixels 200″. In the embodiment of FIG. 10B, three color conversion layers 300″ may be disposed on each of the pixels 200″, or two color conversion layers 300″ and a filter layer 301 in place of the color conversion layer 300″ may be disposed on each of the pixels 200″. The color conversion layers 300″ on each of the pixels 200″ are, for example, two or three quantum dot materials that can be excited to emit red light, green light, and blue light, but not limited thereto.

In the embodiment of FIG. 10A and FIG. 10B, the pixels 200″ are arranged in a first direction (e.g., the x direction), and the sub-pixels 210 of each of the pixels 200″ are arranged in a second direction (e.g., the y-direction) different from the first direction (e.g., the x direction), each of the color conversion layers 300″ extends in the first direction (e.g., the x-direction), and multiple color conversion layers 300″ are respectively disposed on sub-pixels 210 that are in different positions in the second direction (e.g., the y-direction) of each of the pixels 200.

In the embodiment that is not shown, the micro light-emitting diode display device 40 may further include multiple filter layers, which are respectively disposed on the color conversion layers, so that the color purity of the emitted light is higher. The filter layers can also absorb part of the light from the outside, and reflect light of a specific color, thereby reducing the reflected light.

To sum up, in the micro light-emitting diode display device of the embodiment of the disclosure, since the color conversion layer is continuously disposed on the sub-pixels of the pixel along the same direction, the position tolerance of the color conversion layer during manufacture can be increased, improving the yield. Since the color conversion layer has a larger area, the light conversion rate of the micro light-emitting diode display device can be improved to achieve better display quality.

What is claimed is:

1. A micro light-emitting diode display device, comprising:
a display substrate;
a plurality of pixels, disposed on the display substrate, each of the pixels comprising a plurality of sub-pixels, each of the sub-pixels comprising at least one micro light-emitting diode;
at least one color conversion layer, disposed on the pixels;
a plurality of first blocking layers; and
a plurality of second blocking layers,
wherein the at least one color conversion layer is continuously disposed on at least a part of sub-pixels of different pixels along a same direction,
wherein each of the first blocking layers is respectively disposed between two adjacent pixels with a same color conversion layer, and
wherein each of the second blocking layers is respectively disposed between two sub-pixels covered by the color conversion layer of each of the pixels.

2. The micro light-emitting diode display device according to claim 1, wherein a ratio of a first vertical height of the first blocking layers to a second vertical height of the color conversion layer is greater than or equal to 0.5, and a pitch is between two micro light-emitting diodes of two adjacent sub-pixels of two adjacent pixels, a ratio of a width of each of the first blocking layers to the pitch is greater than or equal to 0.5.

3. The micro light-emitting diode display device according to claim 1, further comprising a plurality of light absorbing layers, each of the light absorbing layers is respectively disposed between two adjacent pixels with a same color conversion layer, and the light absorption layer is disposed on the color conversion layer.

4. The micro light-emitting diode display device according to claim 3, wherein a pitch is between two micro light-emitting diodes of two adjacent sub-pixels of two adjacent pixels, a ratio of a width of each of the light absorbing layers to the pitch is greater than or equal to 0.5.

5. The micro light-emitting diode display device according to claim 1, wherein the micro light-emitting diodes of the sub-pixels have a top surface and a bottom surface, and a side surface connecting the top surface and the bottom surface, the color conversion layer covers the top surface and the side surface of a corresponding micro light-emitting diode.

6. The micro light-emitting diode display device according to claim 1, wherein a number of the at least one color conversion layer disposed on each of the pixels is more than one, each of the color conversion layers are respectively disposed on the sub-pixels at different positions of the pixels, and colors of lights converted by different color conversion layers are different from one another.

7. The micro light-emitting diode display device according to claim 1, wherein a wavelength of a light of each of the sub-pixels converted by the color conversion layer is greater than an emission light wavelength of each of the sub-pixels without the color conversion layer.
